(19) United States
(12) Patent Application Publication
(10) Pub. No.: US 2025/0089297 A1
(43) Pub. Date: Mar. 13, 2025

(54) SEMICONDUCTOR DEVICE AND METHOD FOR MANUFACTURING THE SAME

(71) Applicant: SAMSUNG ELECTRONICS CO., LTD., SUWON-SI (KR)

(72) Inventors: JEEWOONG KIM, Suwon-si (KR); SUNGMOON LEE, Suwon-si (KR); YUNSUK NAM, Suwon-si (KR); KEUN HWI CHO, Suwon-si (KR)

(21) Appl. No.: 18/621,413

(22) Filed: Mar. 29, 2024

(30) Foreign Application Priority Data
Sep. 8, 2023 (KR) 10-2023-0119982

(51) Int. Cl. H01L 29/417; H01L 21/285; H01L 23/528; H01L 29/06; H01L 29/08; H01L 29/40; H01L 29/423; H01L 29/45; H01L 29/66; H01L 29/775

(52) U.S. Cl. CPC H10D 30/6729; H01L 21/28518; H01L 23/5286; H10D 30/014; H10D 30/43; H10D 30/6735; H10D 62/121; H10D 62/151; H10D 64/01; H10D 64/017; H10D 64/62

(57) ABSTRACT

A semiconductor device according to embodiment includes: a base insulation layer having a first surface and a second surface facing each other with a thickness therebetween; a channel layer on the first surface of the base insulation layer; a first source/drain pattern and a second source/drain pattern on the first surface of the base insulation layer and arranged in a first direction with the channel layer therebetween; a gate structure, that extends in a second direction crossing the first direction on the first surface of the base insulation layer, and surrounds the channel layer; a first silicide layer on a side wall of a recess pattern that penetrates the first source/drain pattern in a third direction that is perpendicular to the first direction and the second direction; and an interlayer insulation layer that is disposed in the recess pattern.

### CROSS-REFERENCE TO RELATED APPLICATION

This application claims priority under 35 U.S.C. § 119 to Korean Patent Application No. 10-2023-0119982, filed on Sep. 8, 2023, in the Korean Intellectual Property Office, and all the benefits accruing therefrom, the entire contents of which are incorporated herein by reference.

### BACKGROUND

### 1. Field

The present disclosure relates to a semiconductor device, and a method of manufacturing the semiconductor device.

### 2. Description of the Related Art

A semiconductor device is used in various electronic devices, such as a storage device that stores data and a processor that operates and processes data. As the electronics industry develops, various methods are being researched to improve various characteristics of semiconductor devices such as integration, reliability, speed, and functionality. For example, to address the issues relating to the size reduction of the semiconductor device, a semiconductor device with a three-dimensional structure is being proposed.

Recently, research and study has been conducted to improve routing congestion and scale the size of the semiconductor device by placing a power delivery network on a rear of a substrate to route signals provided to the semiconductor device.

### SUMMARY

Principles and embodiments of the present inventive concept relate to a semiconductor device with improved current characteristics and its manufacturing method.

A semiconductor device according to various embodiments includes: a base insulation layer having a first surface and a second surface facing each other with a thickness therebetween; a channel layer on the first surface of the base insulation layer; a first source/drain pattern and a second source/drain pattern on the first surface of the base insulation layer and arranged in a first direction with the channel layer therebetween; a gate structure, that extends in a second direction crossing the first direction on the first surface of the base insulation layer, and surrounds the channel layer; a first silicide layer on a side wall of a recess pattern that penetrates the first source/drain pattern in a third direction that is perpendicular to the first direction and the second direction; and an interlayer insulation layer that is disposed in the recess pattern.

A method of manufacturing a semiconductor device according to an embodiment includes: forming a channel layer, a first source/drain pattern, and a second source/drain pattern arranged in a first direction on a first surface of a substrate; forming a gate structure, that extends in a second direction crossing the first direction on the first surface of the substrate, and surrounds the channel layer; forming an interlayer insulation layer on the channel layer, the first source/drain pattern, the second source/drain pattern, and the gate structure; forming a recess pattern that penetrates the first source/drain pattern in a third direction that is perpendicular to the first direction and the second direction; and forming a first silicide layer extending along a surface profile of the recess pattern; and filling the inside of the recess pattern with an insulating material.

A semiconductor device according to an embodiment includes: a base insulation layer that includes a first surface and a second surface facing each other with a thickness therebetween; a channel layer on the first surface of the base insulation layer; a first source/drain pattern and a second source/drain pattern on the first surface of the base insulation layer, and arranged in a first direction, wherein the channel layer is therebetween; a gate structure that extends in a second direction crossing the first direction on the first surface of the base insulation layer, and surrounds the channel layer in the second direction; a first silicide layer that is on the first source/drain pattern; an interlayer insulation layer that covers the channel layer, the source/drain patterns, and the gate structure; an upper wiring structure on the interlayer insulation layer; a lower wiring structure on the second surface of the base insulation layer; a first through-hole via that penetrates the base insulation layer in the third direction, and connects the recess pattern and the lower wiring structure; and a second through-hole via that penetrates the interlayer insulation layer in the third direction, and electrically connects the second source/drain pattern with the upper wiring structure.

The semiconductor device according to the embodiments may include the recess pattern that penetrates the source/drain region and includes a silicide layer on a side wall thereof, and the current characteristic of the semiconductor device can be improved by transferring current evenly to the channel layers through the silicide layer formed along the sidewall of the recess pattern.

### BRIEF DESCRIPTION OF THE DRAWINGS

FIG. 1 is a top plan view of a semiconductor device according to an embodiment.

FIGS. 2A, 2B, and 2C are cross-sectional views of the semiconductor device according to an embodiment.

FIG. 3 is provided for detailed description of the silicide layer formed in the source/drain area in the semiconductor device according to an embodiment.

FIGS. 4A and 4B are cross-sectional views of a semiconductor device according to an embodiment.

FIG. 5 to FIG. 24 are views of a manufacturing method of a semiconductor device, according to an embodiment.

### DETAILED DESCRIPTION

Hereinafter, with reference to the accompanying drawing, several embodiments will be described. As those skilled in the art would realize, the described embodiments may be modified in various different ways without departing from the scope of the inventive concept and the claims.

Accordingly, the drawings and description are to be regarded as illustrative in nature and not restrictive. Like reference numerals designate like elements throughout the specification.

In addition, the size and thickness of each component shown in the drawing are arbitrarily indicated for convenience of description, and thus the present disclosure is not necessarily limited to what is shown. In the drawings, the thickness of layers, films, panels, regions, etc., are exaggerated for clarity. In addition, in the drawing, for convenience of description, the thickness of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” or “above” a reference portion, the element is located above or below the reference portion, and it does not necessarily mean that the element is located “on” or “above” in a direction opposite to gravity.

In addition, unless explicitly described to the contrary, the word “comprise”, and variations such as “comprises” or “comprising”, will be understood to imply the inclusion of stated elements but not the exclusion of other elements.

Further, throughout the specification, when it is referred to as “planar”, it means the case where a target part is viewed from above, and when it is referred to as “in a cross-section”, it means the case where a cross-section obtained by vertically cutting the target part is viewed from the side.

In the drawing of a semiconductor device according to an embodiment, a gate all around (GAA) and a multi-bridge channel field effect transistor (MBCFETTM), including a nano-wire or nano-sheet, are shown as examples, but are not limited thereto. Depending on embodiments, the semiconductor device may include a fin-type transistor (FinFET), a tunneling transistor (FET), a 3D stack field effect transistor (3DSFET) structure, and a complementary field effect transistor (CFET) structure, including a channel region of a fin-type pattern shape.

Hereinafter, referring to the accompanying drawings, a semiconductor device according to an embodiment will be described.

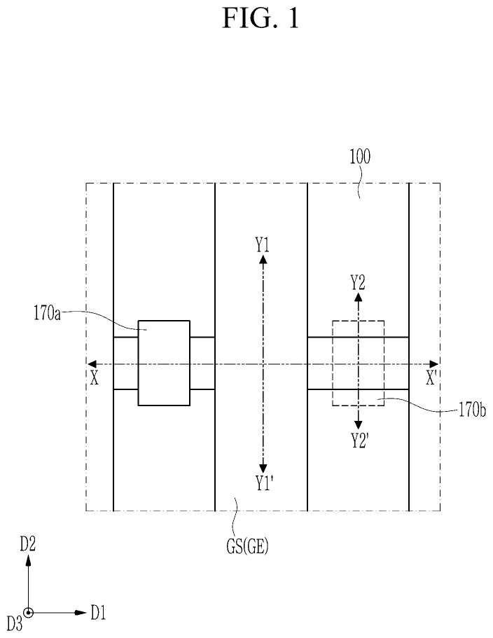

FIG. 1 is a top plan view of a semiconductor device according to an embodiment.

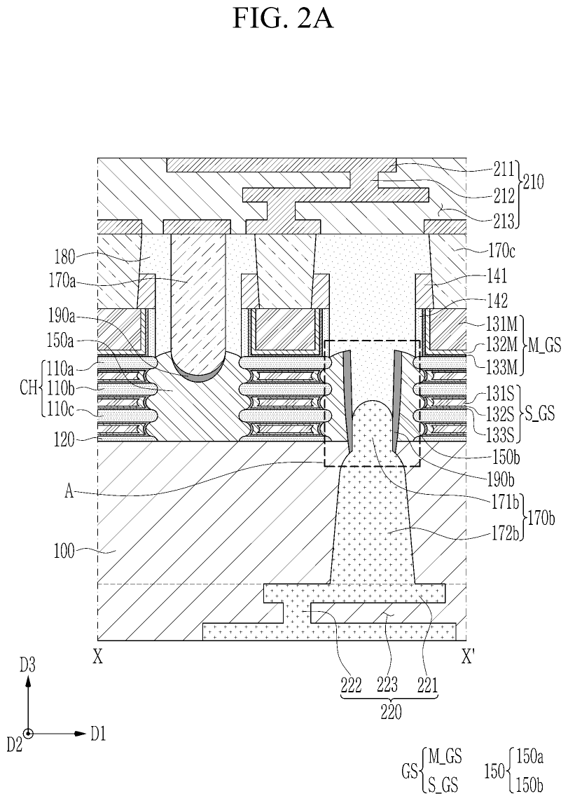

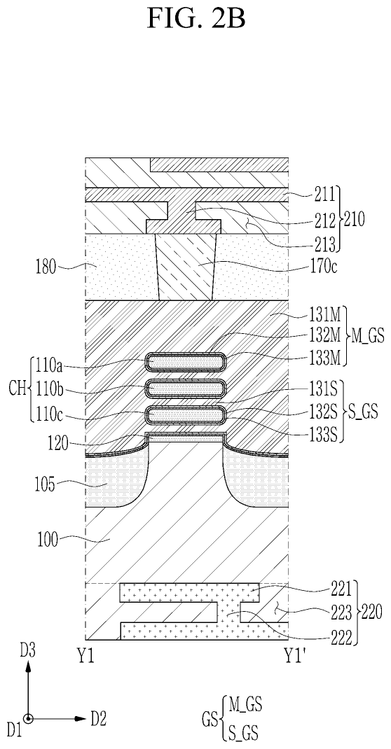

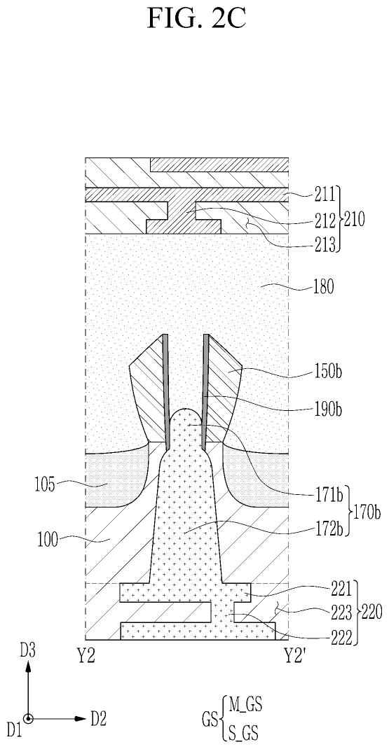

FIGS. 2A, 2B, and 2C are cross-sectional views of the semiconductor device according to an embodiment.

FIG. 2A is a cross-sectional view of FIG. 1, taken along the line X-X′.

FIG. 2B is a cross-sectional view of FIG. 1, taken along the line Y1-Y1′, and FIG. 2C is a cross-sectional view of FIG. 1, taken along the line Y2-Y2′.

Referring to FIG. 1, FIG. 2A, FIG. 2B, and FIG. 2C, a semiconductor device, according to an embodiment, may include a base insulation layer 100, channel layers CH, gate structures M_GS and S_GS, a source/drain pattern 150, an interlayer insulation layer 180, an upper wiring structure 210, a lower wiring structure 220, a first through-hole via 170a, a second through-hole via 170b, and a third through-hole via 170c.

In various embodiments, the base insulation layer 100 may include an insulating material, for example, the base insulation layer 100 may include, an oxide, nitride, nitride oxide, or a combination thereof. The base insulation layer 100 may include an insulating material different from the interlayer insulation layer 180, where for example, the base insulation layer 100 may include silicon nitride (SiN). The base insulation layer 100 is shown as a single layer, but this is for convenience of description, and is not limited thereto. An upper surface and a bottom surface of the base insulation layer 100 may be plane parallel with a first direction D1 and a second direction D2 crossing the first direction D1, and have a thickness therebetween. The upper surface of the base insulation layer 100 opposes the bottom surface of the base insulation layer 100 in a third direction D3, and the separation determines a thickness of the base insulation layer 100. Third direction D3 may be a direction perpendicular to the first direction D1 and the second direction D2. The bottom surface of the base insulation layer 100 may be referred to as a back side of the base insulation layer 100. In some embodiments, a logic circuit may be implemented on the upper surface of the base insulation layer 100.

In various embodiments, the channel layer CH may be disposed on the base insulation layer 100. In an embodiment, a plurality of channel layers 110a, 110b, and 110c may be disposed on the base insulation layer 100. For example, each of the plurality of the channel layers 110a, 110b, and 110c may be a semiconductor layer, where each semiconductor layer may be a nano sheet with a thickness of several nano meters in the third direction D3.

In various embodiments, the channel layer CH may provide a path through which an electrical current flows between two source/drain patterns 150. Referring to FIG. 2A and FIG. 2B, the channel layers 110a, 110b, and 110c may be disposed between the source/drain patterns 150 and electrically connect the source/drain patterns 150. The channel layers 110a, 110b, and 110c may penetrate a part of the gate structure GS in a direction (e.g., the first direction D1) crossing an extension direction of the gate structure GS. For example, each of the channel layers 110a, 110b, and 110c may penetrate the sub-gate structure S_GS in the first direction D1. The channel layers 110a, 110b, and 110c may be arranged at a distance from each other in a vertical direction (e.g., the third direction D3) from the upper surface of the base insulation layer 100. In FIG. 2A and FIG. 2B, the three channel layers 110a, 110b, and 110c are shown as being spaced apart, but this is not limited thereto, and the number of stacked channel layers CH may be varied. The channel layers CH may include a semiconductor material, where for example, the channel layers CH may include group IV semiconductors such as Si and Ge, group III-V compound semiconductors, group II-VI compound semiconductors, and the like.

In an embodiment, a dummy semiconductor layer 120 may be below the channel layer CH, where the dummy semiconductor layer 120 may be between the channel layer 110c and the base insulation layer 100. The dummy semiconductor layer 120 may be between the lowest sub-gate structure S_GS among the plurality of sub-gate structures S_GS and the base insulation layer 100. The upper surface of the dummy semiconductor layer 120 may physically contact a lower surface of the sub-gate structure S_GS positioned at the bottom among the plurality of sub-gate structures S_GS. In an embodiment, a thickness of the dummy semiconductor layer 120 in the third direction D3 may be substantially the same as a thickness in the third direction D3 of each of the channel layers 110a, 110b, and 110c. However, the present disclosure is not limited thereto, and the thickness of the dummy semiconductor layer 120 in the third direction D3 may be different from the thickness in the third direction D3 of each of the channel layers 110a, 110b, and 110c. For example, the thickness of the dummy semiconductor layer 120 in the third direction D3 may be thicker or thinner than the thickness in the third direction D3 of at least one of the channel layers 110a, 110b, and 110c.

In various embodiments, the dummy semiconductor layer 120 may include the same material as the channel layer CH. For example, the dummy semiconductor layer 120 may include group IV semiconductors, such as Si and Ge, group III-V compound semiconductors, group II-VI compound semiconductors, and the like. However, this is not restrictive, and the dummy semiconductor layer 120 may include a material different from the channel layer CH.

In various embodiments, the semiconductor device may further include a field insulation layer 105, where the field insulation layer 105 may be between a main gate electrode 131M and the base insulation layer 100, as shown in FIG. 2B. The field insulation layer 105 may be disposed on the base insulation layer 100. The field insulation layer 105 may not be on the upper surface of the dummy semiconductor layer 120 and/or a side wall of the dummy semiconductor layer 120. However, this is not restrictive, and the field insulation layer 105 may be disposed on the side wall of the dummy semiconductor layer 120. For example, the field insulation layer 105 may cover at least a portion of the side surface of the dummy semiconductor layer 120. An upper surface of the field insulation layer 105 may be below an upper surface of the dummy semiconductor layer 120. The field insulation layer 105 may include, for example, oxide, nitride, oxynitride, or a combination film thereof. The field insulation layer 105 is shown as a single layer, but this is only for convenience of description, and is not limited thereto.

In various embodiments, the gate structure GS may be disposed on the base insulation layer 100. The gate structure GS may include the sub-gate structure S_GS and a main gate structure M_GS. The sub-gate structure S_GS may be disposed on the base insulation layer 100, and the main gate structure M_GS may be disposed on the sub-gate structure S_GS. The gate structure GS may extend in a direction different from the direction in which the source/drain patterns 150 are arranged on the base insulation layer 100. For example, the gate structure GS may extend in a direction (e.g., the second direction D2) crossing the direction in which the source/drain patterns 150 are arranged on the base insulation layer 100. The gate structure GS may be disposed on the base insulation layer 100. The gate structures GS may be arranged at a distance from each other in the first direction D1, where adjacent gate structures GS may be electrically separated from each other.

In various embodiments, the main gate structure M_GS may be disposed above channel layer 110a positioned at the top of the stacked channel layers CH. The main gate structure M_GS may also be disposed on a side surface of a structure in which the channel layers 110a, 110b, and 110c and the sub-gate structure S_GS are stacked. The main gate structure M_GS may surround the channel layers 110a, 110b, and 110c and the sub-gate structures S_GS in the second direction D2.

In various embodiments, the sub-gate structures S_GS may contact the source/drain pattern 150. For example, the sub-gate structure S_GS may directly contact the source/drain pattern 150. The source/drain patterns 150 may be disposed on both sides of the sub-gate structure S_GS. Each sub-gate structure S_GS may be formed of multiple layers. For example, teach sub-gate structure S_GS may include a sub-gate electrode 131S, a sub-gate insulation layer 132S, and a sub-interface insulation layer 133S. The sub-gate structures S_GS and the channel layers 110a, 110b, and 110c may be alternately stacked in the third direction D3. The sub-gate structures S_GS may surround other surfaces except a surface connected to the source/drain patterns 150 of the channel layers 110a, 110b, and 110cs along with the main gate structure M_GS in the third direction D3. The sub-gate structure S_GS may surround the channel layers CH in the direction in which the gate structure GS extends (e.g., the second direction D2).

In FIG. 2A and FIG. 2B, it is illustrated that three sub-gate structures S_GS are arranged in the third direction D3, but the number of the sub-gate structures S_GS arranged is not limited to this. For example, the gate structure GS may include four sub-gate structures S_GS.

In various embodiments, the sub-gate electrode 131S may contain at least one of a metal, a metal alloy, a conductive metal nitride, a metal silicide, a doped semiconductor material, a conductive metal oxide, or a combination thereof. The sub-gate electrode 131S may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium niobium (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but this is not restrictive. The conductive metal oxide may include, but are not limited to, oxidized forms of the materials described above.

In various embodiments, a sub-interface insulation layer 133S may be disposed around the circumference of the channel layer CH, where the sub-interface insulation layer 133S may surround surfaces other than a surface of the channel layer CH connected to the source/drain pattern 150. The sub-interface insulation layer 133S may directly contact the source/drain pattern 150 and the channel layer CH. The sub-interface insulation layer 133S may be disposed between the channel layer CH and the sub-gate insulation layer 132S. The sub-interface insulation layer 133S may include, for example, silicon oxide (SiO₂).

In various embodiments, the sub-gate insulation layer 132S may extend along an upper surface of the sub-interface insulation layer 133S. The sub-gate insulation layer 132S may surround the channel layer CH. For example, the sub-gate insulation layer 132S may surround surfaces excluding a surface connected with the source/drain pattern 150 of the channel layer CH. The sub-gate insulation layer 132S may be disposed around the circumference of the channel layer CH. The sub-gate insulation layer 132S may be disposed between the sub-gate electrode 131S and the sub-interface insulation layer 133S. The sub-gate insulation layer 132S may include, for example, a high dielectric constant material, where the high dielectric constant materials may include materials with a dielectric constant greater than silicon oxide (SiO₂), such as hafnium oxide (HfO), aluminum oxide (AlO), or tantalum oxide (TaO).

In various embodiments, the main gate structure M_GS may be disposed on the sub-gate structure S_GS and the channel layer CH. The main gate structure M_GS may be disposed on an upper surface of the channel layer CH, where the main gate structure M_GS may be on the channel layer 110a positioned at the top of the stacked channel layers CH. Each main gate structure M_GS may be formed of a plurality of layers. For example, the main gate structure M_GS may include a main gate electrode 131M, a main interface insulation layer 133M, and a main gate insulation layer 132M. The main gate structure M_GS, together with the sub-gate structure S_GS, may surround other surfaces of at least one (e.g., 110a) of the channel layers CH except the surface connected to the source/drain pattern 150. The main gate structure M_GS, together with the sub-gate structure S_GS, may surround the channel layer CH in a direction in which the gate structure GS extends (e.g., the second direction D2).

In various embodiments, the main gate electrode 131M may be disposed on the sub-gate structure S_GS and the channel layer CH. The main gate electrode 131M may be disposed on an upper surface of the channel layer CH, where the main gate electrode 131M may be on channel layer 110a positioned at the top of the stacked channel layers CH. The main gate electrode 131M may include the same material as the sub-gate electrode 131S. For example, the main gate electrode 131M may include at least one of a metal, a metal alloy, conductive metal nitride, metal silicide, a doped semiconductor material, conductive metal oxide, and conductive metal oxide.

In various embodiments, the main interface insulation layer 133M may extend along the upper surface of the channel layer CH. The main interface insulation layer 133M may include, for example, silicon oxide (SiO₂). The main gate insulation layer 132M may extend along a side surface and a bottom surface of the main gate electrode 131M. The main gate insulation layer 132M may include, for example, a high dielectric constant material.

In various embodiments, the gate spacer 142 may be located on a side surface of the main gate electrode 131M, where the main interface insulation layer 133M and main gate insulation layer 132M may be between the gate spacer 142 and the main gate electrode 131M. The gate spacer 142 may not be between the dummy semiconductor layer 120 and the channel layer CH. The gate spacer 142 may not be between the channels CH adjacent to the third direction D3.

In various embodiments, the gate spacer 142 may include, for example, silicon nitride (SiN), silicon oxide (SiON), silicon oxide (SiO₂), silicon carbonitride (SiOCN), silicon boron nitride (SiBN), silicon acid boron nitride (SiOBN), silicon oxycarbide (SiOC), and combinations thereof. The gate spacer 142 is shown as a single layer, but this is only for convenience of description and is not limited thereto.

In various embodiments, the capping layer 141 may be disposed on the main gate structure M_GS and the gate spacer 142, where the capping layer 141 may be adjacent to a third through-hole via 170c. A top surface of the gate spacer 142 may be covered by the capping layer 141.

In various embodiments, the capping layer 141 may include at least one of silicon nitride (SiN), silicon oxide (SiON), silicon carbonitride (SiCN), silicon carbonitride (SiOCN), or a combination thereof. The capping layer 141 may include a material having etch selectivity to the interlayer insulation layer 180.

In various embodiments, the source/drain pattern 150 may be disposed on the base insulation layer 100. In an embodiment, a bottom surface of the source/drain pattern 150 may be at substantially the same level as the bottom surface of the dummy semiconductor layer 120, where the source/drain pattern 150 and dummy semiconductor layer 120 may be on the upper surface of the base insulation layer 100. The source/drain pattern 150 may be disposed on both sides of the channel layer CH and/or sub-gate structure S_GS. The two source/drain patterns 150 may be arranged in a direction (e.g., the first direction D1) that crosses the direction in which the gate structure GS extends, with the channel layer CH or sub-gate structure S_GS in between. The source/drain pattern 150 may directly contact the channel layer CH and sub-gate structure S_GS, where the source/drain pattern 150 may directly contact the sub-interface insulation layer 133S and the end faces of the channel layers 110a, 110b, and 110c. An inner space may be further disposed between the source/drain pattern 150 and the sub-interface insulation layer 133S.

In various embodiments, the inner spacer may include, for example, silicon nitride (SiN), silicon oxide (SiON), silicon oxide (SiO₂), silicon carbonitride (SiOCN), silicon boron nitride (SiBN), silicon acid boron nitride (SiOBN), and silicon oxycarbide (SiOC), or a combination thereof.

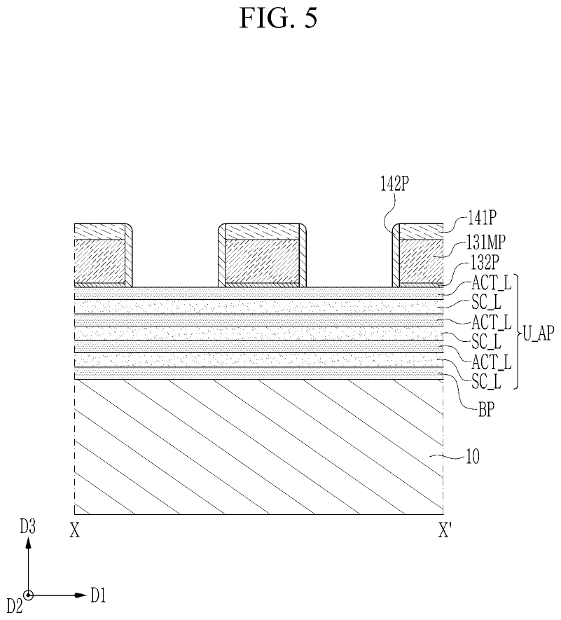

In various embodiments, the source/drain pattern 150 may be formed of an epitaxial formed by selective epitaxial growth (SEG) in a region where an active pattern ACT_L (refer to FIG. 5) and a part of a sacrificial pattern SC_L (refer to FIG. 5), which will be described later, are recessed. In other words, the source/drain patterns 150 may fill the region where the active pattern ACT_L (refer to FIG. 5) and the part of the sacrificial pattern SC_L (refer to FIG. 5), which will be described later, are recessed.

In various embodiments, the source/drain patterns 150 may include a semiconductor material. The source/drain pattern 150 may include, for example, silicon or germanium. In addition, the source/drain pattern 150 may include, for example, a binary compound containing at least two of carbon (C), silicon (Si), germanium (Ge), and tin (Sn), or a ternary compound. For example, the source/drain pattern 150 may include silicon, silicon-germanium, germanium, silicon carbide, and the like, but is not limited thereto.

In an embodiment, the source/drain patterns 150 may include a first source/drain pattern 150a and a second source/drain pattern 150b. Referring to FIG. 2A, among the source/drain patterns 150, a first source/drain pattern 150a may be connected with an upper wiring structure 210 through a first through-hole via 170a. A first silicide layer 190a may be disposed between the first through-hole via 170a and the first source/drain pattern 150a. The first silicide layer 190a may be a metal silicide layer.

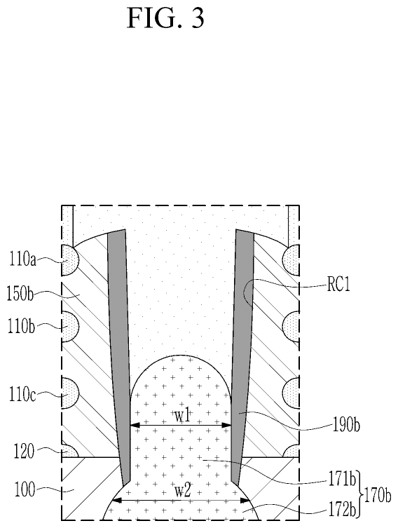

In various embodiments, the second source/drain pattern 150b may be electrically connected with a lower wiring structure 220 through a second through-hole via 170b, where the second through-hole via 170b may extend through the base insulation layer 100. A second silicide layer 190b may be disposed between the second through-hole via 170b and the second source/drain pattern 150b, where the second silicide layer 190b may be on a first region 171b of the second through-hole via 170b. The semiconductor device may further include a recess pattern RC1 (refer to FIG. 3) penetrating through one of the source/drain patterns 150 in a vertical direction. In FIG. 2A, it is illustrated that the first source/drain pattern 150a is connected with the upper wiring structure 210 and the second source/drain pattern 150b is connected with the lower wiring structure 220, but two source/drain patterns 150 disposed at both sides of the channel layer CH may be connected with the lower wiring structure 220.

In various embodiments, the interlayer insulation layer 180 may cover the channel layer CH, the gate structure GS, and the source/drain patterns 150. The interlayer insulation layer 180 may include, for example, at least one of silicon oxide (Si0₂), silicon nitride (SiN), silicon oxynitride (SiON), or a low dielectric constant material. The low dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams, such as polypropylene oxide, carbon doped silicon oxide (CDO), organo silicate glass (OSG), silk, amorphous fluorinated carbon, silica aerogels, silica xerogels, mesoporous silica, or a combination thereof, but this is not restrictive. In an embodiment, the interlayer insulation layer 180 may include a different material than the base insulation layer 100, where for example, the interlayer insulation layer 180 may include silicon oxide (SiO₂).

In various embodiments, the upper wiring structure 210 may be disposed on the interlayer insulation layer 180. The upper wiring structure 210 may include upper wires 211, upper vias 212, and an upper insulation layer 213, where the upper insulation layer 213 may cover at least a portion of the interlayer insulation layer 180. The upper wires 211 and the upper vias 212 may include a metal (e.g., copper). The upper insulation layer 213 may be between and surround the upper wires 211 and the upper vias 212 to electrically insulate them. The upper insulation layer 213 may cover the interlayer insulation layer 180 and the upper wires 211, where the upper wires 211 and the upper vias 212 may be disposed within the upper insulation layer 213. The upper insulation layer 213 may include, for example, at least one of silicon oxide (Si0₂), silicon nitride (SiN), silicon oxynitride (SiON), or a low dielectric constant material.

In various embodiments, the lower wiring structure 220 may be disposed on a lower surface of the base insulation layer 100. The lower wiring structure 220 may be configured to supply power to at least one of the source/drain patterns 150, where for example, the lower wiring structure 220 may be a power delivery network. The lower wiring structure 220 may include lower wires 221, lower vias 222, and a lower insulation layer 223, where the lower wires 221 and the lower vias 222 may be disposed within the lower insulation layer 223. The lower insulation layer 223 may cover at least a portion of the lower surface of the base insulation layer 100. The lower wires 221 and the lower vias 222 may be disposed on a lower surface of the base insulation layer 100. The lower wires 221 and the lower vias 222 may include, for example, a metal (e.g., copper).

In various embodiments, the lower insulation layer 223 may be disposed between and surround the lower wires 221, and the lower vias 222 to electrically insulate them. The lower insulation layer 223 may cover the lower wires 221, where the lower wire 221 and the lower vias 222 may be disposed in the lower insulation layer 223. The lower insulation layer 223 may include, for example, at least one of silicon oxide (Si0₂), silicon nitride (SiN), silicon oxynitride (SiON), or a low dielectric constant material.

In various embodiments, the first through-hole via 170a may penetrate a top surface of the interlayer insulation layer 180 in the third direction D3. One end of the first through-hole via 170a may be electrically connected with the upper wire 211 of the upper wiring structure 210 and the opposite end may be electrically connected with the first source/drain pattern 150a. In an embodiment, a first silicide layer 190a may be disposed at an interface of the first through-hole via 170a and the first source/drain pattern 150a. The first through-hole via 170a may include at least one of a metal, a metal alloy, conductive metal nitride, conductive metal carbide, conductive metal oxide, conductive metal carbonitride, or a two-dimensional material. The metal may include at least one of titanium (Ti), tantalum (Ta), tungsten (W), nickel (Ni), cobalt (Co), or platinum (Pt). The conductive metal nitride may include at least one of titanium nitride (TiN), tantalum nitride (TaN), tungsten nitride (WN), nickel nitride (NiN), cobalt nitride (CON), or platinum nitride (PtN).

In various embodiments, the second through-hole via 170b may penetrate a bottom surface of the base insulation layer 100 in the third direction D3. One end of the second through-hole via 170b may be electrically connected with the lower wire 221 of the lower wiring structure 220 and the opposite end may be electrically connected with the second source/drain pattern 150b. The second silicide layer 190b may be disposed between the second through-hole via 170b and the second source/drain pattern 150b. The second through-hole via 170b may be electrically connected with the second source/drain pattern 150b through the second silicide layer 190b. In and embodiment, the second through-hole via 170b may include a first region 171b and a second region 172b, where the first region 171b may be directly on the second region 172b. One end of the first region 171b may contact the interlayer insulation layer 180 and the other end may contact the second region 172b. A side wall of the first region 171b may contact the second silicide layer 190b. The first region 171b penetrates the top surface of the base insulation layer 100 and may protrude in the third direction D3. In an embodiment, the second silicide layer 190b may be disposed at an interface of the first region 171b and the second source/drain pattern 150b. One end of the second region 172b may be physically and electrically connected with the first region 171b and the other end may be electrically connected with the lower wiring structure 220.

In various embodiments, the second through-hole via 170b may include at least one of a metal, a metal alloy, conductive metal nitride, conductive metal carbide, conductive metal oxide, conductive metal carbonitride, or a two-dimensional material. The metal may include at least one of titanium (Ti), tantalum (Ta), tungsten (W), nickel (Ni), cobalt (Co), or platinum (Pt). The conductive metal nitride may include at least one of titanium nitride (TIN), tantalum nitride (TaN), tungsten nitride (WN), nickel nitride (NiN), cobalt nitride (CON), or platinum nitride (PtN).

In various embodiments, the third through-hole via 170c may penetrate the interlayer insulation layer 180 and the capping layer 141 in the third direction D3, as shown in FIG. 2B. One end of the third through-hole via 170c may be electrically connected with the main gate electrode 131M, and the opposite end may be electrically connected with the upper wiring structure 210. The third through-hole via 170c may connect the upper wire 211 to a top surface of the main gate electrode 131M by extending through the capping layer 141 in the third direction D3, as shown in FIG. 2A. A signal may be provided to the gate structure GS through the upper wiring structure 210 and the third through-hole via 170c. The third through-hole via 170c may include the same material as the first and second through-hole vias 170a and 170b. For example, the third through-hole via 170c may include at least one of a metal, a metal alloy, conductive metal nitride, conductive metal carbide, conductive metal oxide, conductive metal carbonitride, or a two-dimensional material. The metal may include at least one of titanium (Ti), tantalum (Ta), tungsten (W), nickel (Ni), cobalt (Co), or platinum (Pt). The conductive metal nitride may include at least one of titanium nitride (TiN), tantalum nitride (TaN), tungsten nitride (WN), nickel nitride (NiN), cobalt nitride (CON), or platinum nitride (PtN).

FIG. 3 is provided for detailed description of the silicide layer formed in the source/drain area in the semiconductor device, according to an embodiment.

In various embodiments, the semiconductor device may include a recess pattern RC1 penetrating one or more of the source/drain patterns 150 in a vertical direction. Referring to FIG. 3, the recess pattern RC1 may penetrate some areas of the second source/drain pattern 150b in a direction that is perpendicular to the top surface of the second source/drain pattern 150b (e.g., third direction D3). The recess pattern RC1 may extend into the base insulation layer 100 while penetrating a bottom surface of the second source/drain pattern 150b.

In various embodiments, the second silicide layer 190b may be disposed on a side wall of the recess pattern RC1, where the second silicide layer 190b may extend along a surface profile of the side wall of the recess pattern RC1. The second silicide layer 190b may be a metal silicide layer. An insulation material may fill the inside of the recess pattern RC1, where the insulating material that fills the inside of the recess pattern RC1 may include the same insulating material as the interlayer insulation layer 180. For example, the interlayer insulation layer 180 described with reference to FIG. 2A may cover the second silicide layer 190b disposed along the sidewall profile of the recess pattern RC1.

In various embodiments, a lower surface of recess pattern RC1 may be penetrated by the second through-hole via 170b. Referring to FIG. 3, the first region 171b of the second through-hole via 170b penetrates the lower surface of the recess pattern RC1 in the third direction and thus may protrude into the recess pattern RC1. A top surface of the first region 171b of the second through-hole via 170b may be located at a higher level than the interface between the second source/drain pattern 150b and the base insulation layer 100. In an embodiment, a width of the first region 171b in the first direction D1 may be less than a width of the second region 172b in the first direction D1. In an embodiment, a maximum width of the first region 171b in the first direction D1 may be less than a maximum width of the second region 172b in the first direction D1.

In an embodiment, the first region 171b of the second through-hole via 170b may directly contact a portion of the second silicide layer 190b on the sidewall of the recess pattern RC1. A current supplied through the second through-hole via 170b may flow along the sidewall of the recess pattern RC1 through the second silicide layer 190b.

Referring to FIG. 3, the second silicide layer 190b may be disposed on the entire sidewall of the recess pattern RC1 that penetrates the second source/drain pattern 150b. The second silicide layer 190b may further extend toward the lower surface of the base insulation layer 100 with reference to the interface between the second source drain pattern 150b and the base insulation layer 100. An interface of the end of the second silicide layer 190b with the second region 172b may be between the upper surface of the base insulation layer 100 and the lower surface of the base insulation layer 100; however, this is not restrictive, and the interface of the end of the second silicide layer 190b and the second region 172b may be located at substantially the same height as the interface of the second source drain pattern 150b and the base insulation layer 100. The channel layers 110a, 110b, and 110c in contact with the second source/drain pattern 150b may overlap with the second silicide layer 190b in the first direction D1. The second silicide layer 190b may provide an electrical path through which the current supplied through the second through-hole via 170b flows along the sidewall of the recess pattern RC1. According to an embodiment, the current supplied through the second through-hole via 17b from the lower wiring structure 220 (refer to FIG. 2) may be evenly transmitted to all the channel layers 110a, 110b, and 110c through the sidewall of the recess pattern RC1. In addition, a distance between the respective channel layers 110a, 110b, and 110c and the second silicide layer 190b may be reduced, such that a series resistance component due to the source/drain pattern 150 can be reduced and the current characteristic of the semiconductor device can be improved.

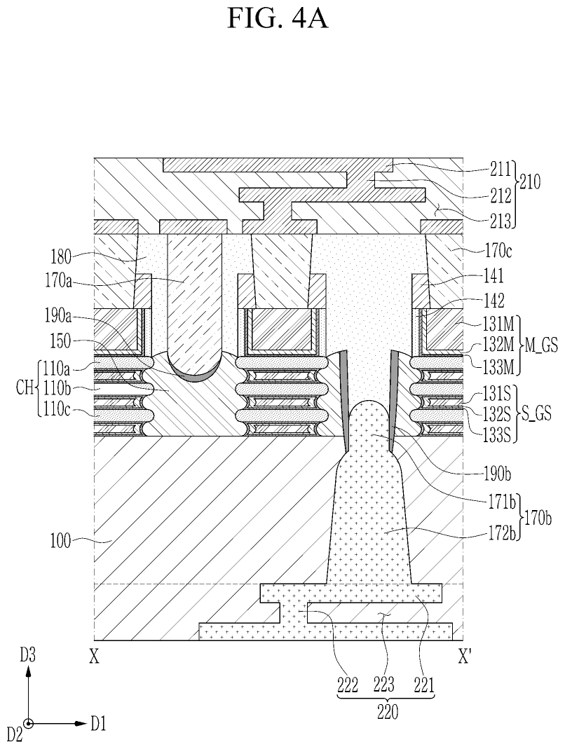

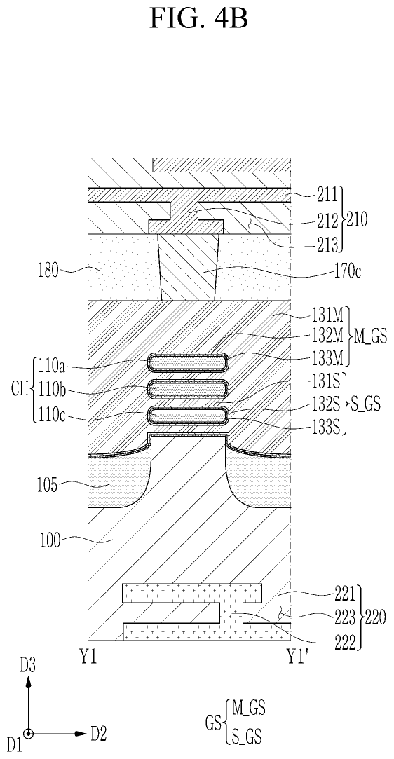

FIG. 4A and FIG. 4B are cross-sectional views of a semiconductor device according to an embodiment.

FIG. 4A is a cross-sectional view of FIG. 1, taken along the line X-X′.

FIG. 4B is a cross-sectional view of FIG. 1, taken along the line Y1-Y1′.

Referring to FIG. 4A and FIG. 4B, a semiconductor device may include base insulation layer 100, channel layers CH, gate structures M_GS and S_GS, source/drain pattern 150, interlayer insulation layer 180, upper wiring structure 210, lower wiring structure 220, first through-hole via 170a, second through-hole via 170b, and a third through-hole via 170c.

In various embodiments, the semiconductor device may not include the dummy semiconductor layer 120. In the case of the semiconductor device described with reference to FIG. 2A and FIG. 2B, the dummy layer 120 is shown in the lower portion of the lowest channel layer 110c, but in the case of the semiconductor device shown in FIG. 4, a dummy semiconductor layer 120 may not be in a lower portion of the lowest channel layer 110c. A lower surface of a source/drain pattern 150 may be located at the substantially same level as a lower surface of a sub-gate structure S_GS. The source/drain pattern 150 and the lower surface of the sub-gate structure S_GS may directly contact the upper surface of the base insulation layer 100.

Detailed configurations and connection relationship of the semiconductor device of FIG. 4A and FIG. 4B can be the same as those of the semiconductor device described with reference to FIG. 2A and FIG. 2B, other than the presence of the dummy semiconductor layer, and therefore a detailed description is omitted.

FIG. 5 to FIG. 24 illustrate a manufacturing method of a semiconductor device, according to an embodiment.

As shown in FIG. 5, a bottom pattern BP and an upper pattern structure U_AP may be formed on a substrate 10. The substrate 10 may be a silicon-on-insulator (SOI) or bulk silicon. Alternatively, the substrate 10 may be a silicon substrate, or may include other material, for example, silicon germanium (SiGe), silicon germanium on insulator (SGOI), indium antimonide, a lead tellurium compound, indium arsenic, indium phosphide, gallium arsenic, or gallium antimony, but is not limited thereto.

In various embodiments, the upper pattern structure U_AP may be disposed on the bottom pattern BP, where the upper pattern structure U_AP may be a multi-layer structure. The upper pattern structure U_AP may include a sacrificial pattern SC_L and an active pattern ACT_L alternately stacked on the bottom pattern BP. The sacrificial pattern SC_L may include silicon germanium (SiGe), and the active pattern ACT_L may include silicon (Si).

In various embodiments, the bottom pattern BP may not be formed in a manufacturing process of the semiconductor device. In this case, the upper pattern structure U_AP may be disposed directly on the substrate 10, where the bottom surface of the upper pattern structure U_AP may directly contact the upper surface of the substrate 10. The upper pattern structure U_AP may include the sacrificial pattern SC_L and the active pattern ACT_L alternately stacked on the substrate 10.

In various embodiments, a preliminary gate insulation layer 132P, a preliminary main gate electrode 131MP, and a preliminary capping layer 141P are formed on the upper pattern structure U_AP. The preliminary gate insulation layer 132P may include, for example, silicon oxide (SiO₂), but is not limited thereto. The preliminary main gate electrode 131MP may include, for example, polysilicon, but is not limited thereto. The preliminary capping layer 141P may include, for example, silicon nitride, but is not limited thereto.

In various embodiments, the preliminary gate spacer 142P may be formed on both sides of the preliminary main gate electrode 131MP.

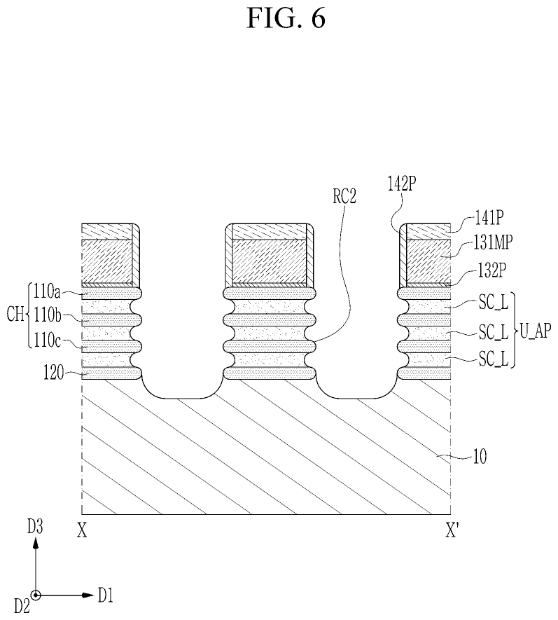

As shown in FIG. 6, a source/drain recess RC2 may be formed by etching at least a part of the upper pattern structure U_AP using the preliminary capping layer 142P and the preliminary gate spacer 142P as a mask. The source/drain recess RC2 may extend through the bottom pattern BP, described with reference to FIG. 5. A portion of the source/drain recess RC2 may be formed inside the substrate 10. As shown in FIG. 6, after forming the source/drain recess RC2, an indent process for the sacrificial layer SC_L may be carried out. In the indent process, the sacrificial layer SC_L is etched using a wet etching or dry etching method, such that a length of the sacrificial layer SC_L in the first direction D1 may be reduced, where a side of the sacrificial layer SC_L that contacts the source/drain recess RC2 may have a shape concave toward the source/drain recess RC2.

As the source/drain recess RC2 is formed, the active pattern ACT_L and the bottom pattern BP, described with reference to FIG. 5, are separated, such that the channel layers 110a, 110b, and 110c and the dummy semiconductor layer 120 may each be formed. The channel layers 110a, 110b, and 110c and the dummy semiconductor layer 120 may be disposed at both sides of the source/drain recess RC2. However, as described with reference to FIG. 5, when the bottom pattern BP is not formed on the substrate 10, a part of the substrate 10 may form the dummy semiconductor layer 120. The source/drain recess RC2 is formed, at least a part of the substrate 10 is etched, and a part of an upper side of the substrate 10 remaining at both sides of the source/drain recess RC2 may form the dummy semiconductor layer 120. The channel layers 110a, 110b, and 110c and the sacrificial pattern SC_L may be alternately stacked in the third direction D3. In this case, the channel layers 110a, 110b, and 110cs may respectively have the same of different lengths.

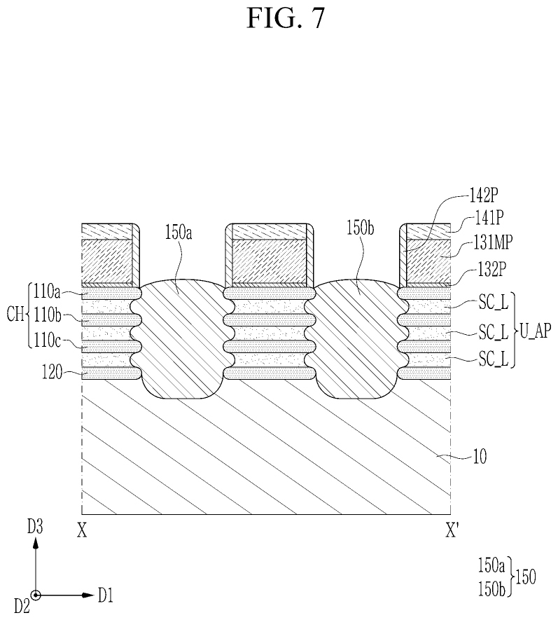

As shown in FIG. 7, the source/drain pattern 150 may be formed in the source/drain recess RC2, where the source/drain pattern 150 may be formed on the substrate 10. The source/drain pattern 150 may be formed using an epitaxial growth method, where an inner wall of the source/drain recess RC2 may be used as a seed surface. The source/drain pattern 150 may extend through the dummy semiconductor layer 120. The source/drain pattern 150 may directly contact the substrate 10 and the dummy semiconductor layer 120. The source/drain pattern 150 may directly contact the channel layers 110a, 110b, and 110c and the sacrificial layer SC_L. The source/drain pattern 150 may include silicon (Si), germanium (Ge), or silicon germanium (SiGe). The source/drain pattern 150 may be formed of multiple areas with different silicon (Si) or germanium (Ge) concentrations, where for example, the concentration of germanium (Ge) in the source/drain pattern 150 may be lower in an area adjacent to the inner wall of the source/drain recess RC2 than in the central area of the source/drain recess RC2.

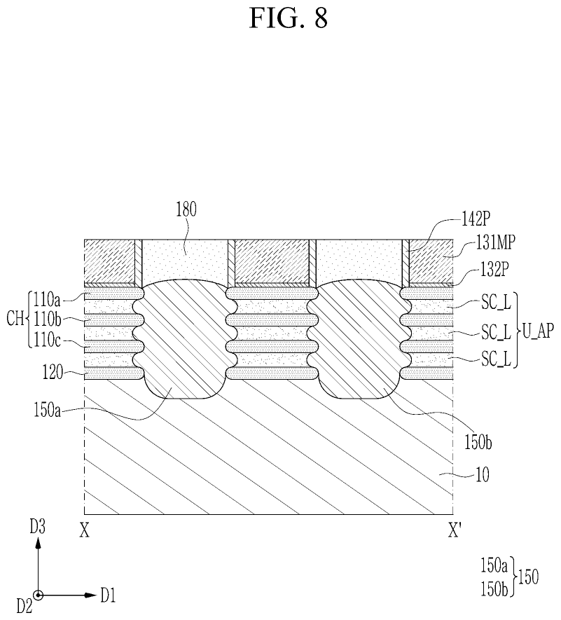

As shown in FIG. 8, an interlayer insulation layer 180 may be formed on the source/drain pattern 150, where the interlayer insulation layer 180 may be formed in an upper portion of the source/drain recess RC2. A part of the interlayer insulation layer 180 and the preliminary capping layer 141P may be removed to expose an upper surface of the preliminary main gate electrode 131MP. A part of the preliminary gate spacer 142P may be removed together with the preliminary capping layer 141P, such that a gate spacer 142 can be formed.

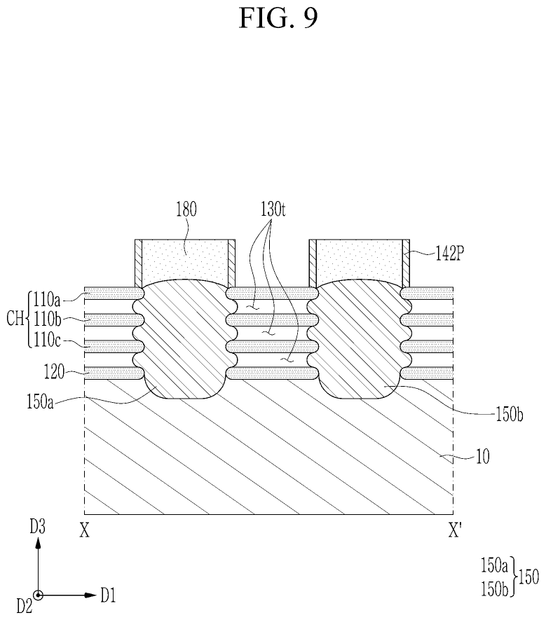

As shown in FIG. 9, the preliminary gate insulation layer 132P and the preliminary main gate electrode 131MP are removed to expose the upper pattern structure U_AP between the gate spacers 142. Gate trenches 130t are formed between the channel layers CH by removing the sacrificial pattern SC_L.

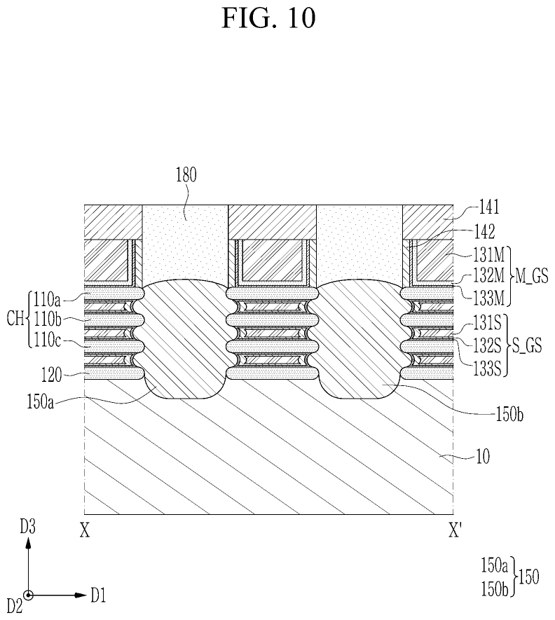

As shown in FIG. 10, a sub-interface insulation layer 133S, a sub-gate insulation layer 132S, and a sub-gate electrode 131S may be sequentially formed in the gate trench 130t, where the sub-interface insulation layer 133S, sub-gate insulation layer 132S, and sub-gate electrode 131S may be sequentially formed on the channel layers 110b and 110c. In addition, a main interface insulation layer 133M, a main gate insulation layer 132M, a main gate electrode 131M, and a capping layer 141 may be sequentially formed, where the main interface insulation layer 133M, main gate insulation layer 132M, and main gate electrode 131M may be sequentially formed on the channel layer 110a.

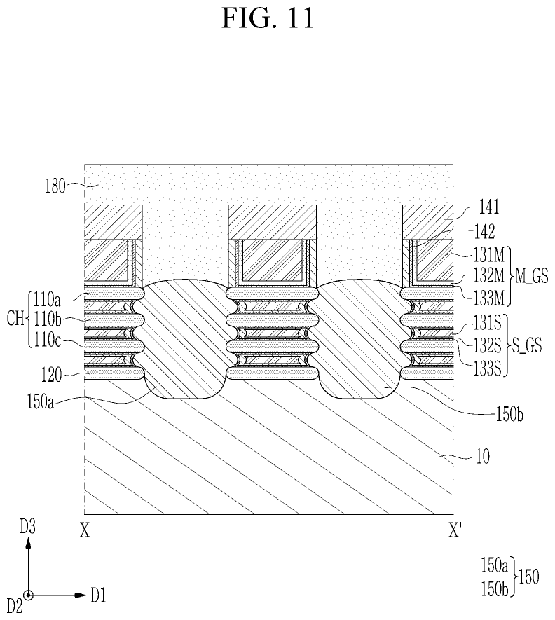

As shown in FIG. 11, an interlayer insulation layer 180 may be formed on the capping layer 141, where an upper surface of the interlayer insulation layer 180 may be at a higher level than an upper surface of the capping layer 141. The additionally formed interlayer insulation layer 180 may include the same insulating material as the initially formed interlayer insulation layer 180, which was previously formed on the source/drain pattern 150. A boundary may not be visible between the interlayer insulation layer 180 that is formed later and the interlayer insulation layer 180 that was formed earlier.

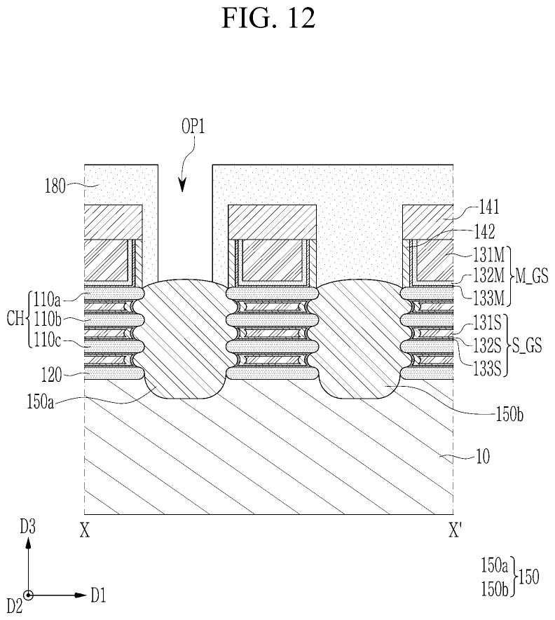

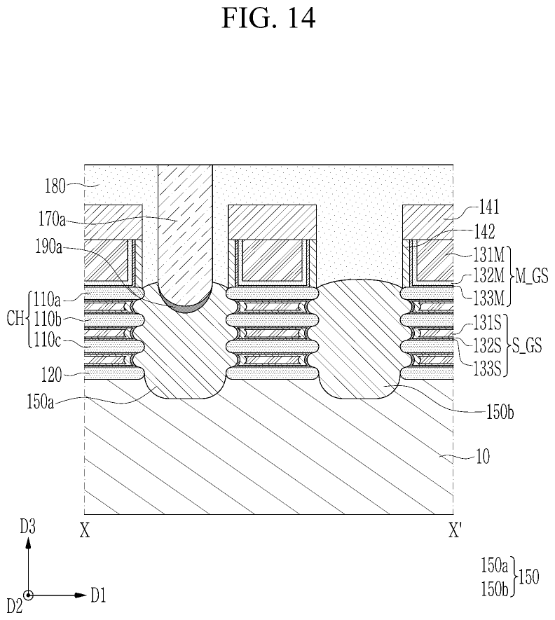

As shown in FIG. 12, a portion of the interlayer insulation layer 180 is removed to form a first opening OP1, where the portion of the interlayer insulation layer 180 may be removed by etching. In this case, with respect to the interlayer insulation layer 180, a portion of the interlayer insulation layer 180 may be etched using an etching solution having a higher etch selectivity compared to the source/drain pattern 150. In another embodiment, a part of the interlayer insulation layer 180 may be etched through a dry etching process. The upper surface of the first source/drain pattern 150a may be partially exposed subsequent to removal of the portion of the interlayer insulation layer 180. The first opening OP1 may be formed for a first through-hole via 170a (refer to FIG. 14).

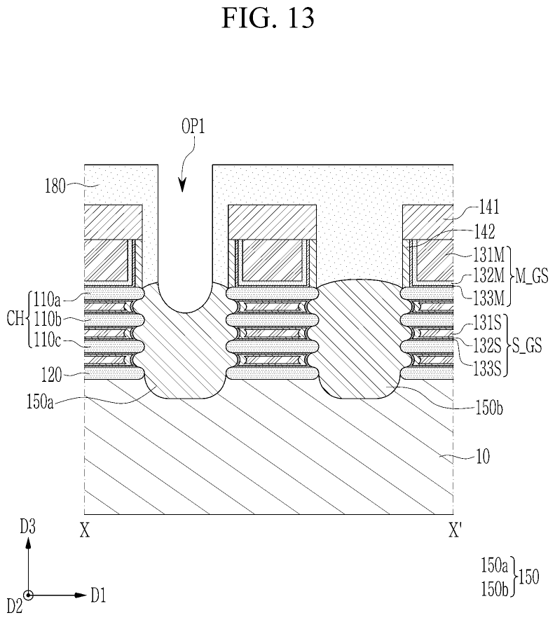

As shown in FIG. 13, a portion of the upper surface of the first source/drain pattern 150a may be etched. The upper surface of the first source/drain pattern 150a may be curved downward toward a top surface direction of the substrate 10. The portion of the upper surface of the first source/drain pattern 150a may be etched using an etching solution with higher etch selectivity compared to the interlayer insulation layer 180, and/or a part of the upper surface of the first source/drain pattern 150a may be etched through a dry etching process. In an embodiment, while the first opening OP1 overlapping a part of the upper surface of the first source/drain pattern 150a is formed in the third direction D3, a part of the interlayer insulation layer 180 disposed on the second source/drain pattern 150b may be masked. Accordingly, while the first opening OP1 is formed, the interlayer insulation layer 180 disposed on the second source/drain pattern 150b may not be etched.

As shown in FIG. 14, a first silicide layer 190a and a first through-hole via 170a may be formed in the first opening OP1. The first silicide layer 190a may be formed at an interface of the first source/drain pattern 150a and the first through-hole via 170a, where the first silicide layer 190a may be formed on the exposed portion of the upper surface of the first source/drain pattern 150a. The first silicide layer 190a may be formed along the surface profile of the first opening OP1. The first silicide layer 190a may be a metal silicide layer. In an embodiment, the first silicide layer 190a may be formed using a chemical vapor deposition (CVD) method. The first silicide layer 190a may be selectively formed on the surface of the first source/drain pattern 150a.

After the first silicide layer 190a is formed inside the first opening OP1, the first through-hole via 170a may be formed in the remaining region of the first opening OP1. The first through-hole via 170a may be formed on the first silicide layer 190a. The first through-hole via 170a may be electrically connected with the first source/drain pattern 150a through the first silicide layer 190a. After forming the first silicide layer 190a, a process for depositing a barrier metal coving a side wall or a lower surface of the first opening OP1 may further be carried out before the first through-hole via 170a is formed. The barrier metal may include a metal, a metal alloy, and/or a conductive metal nitride.

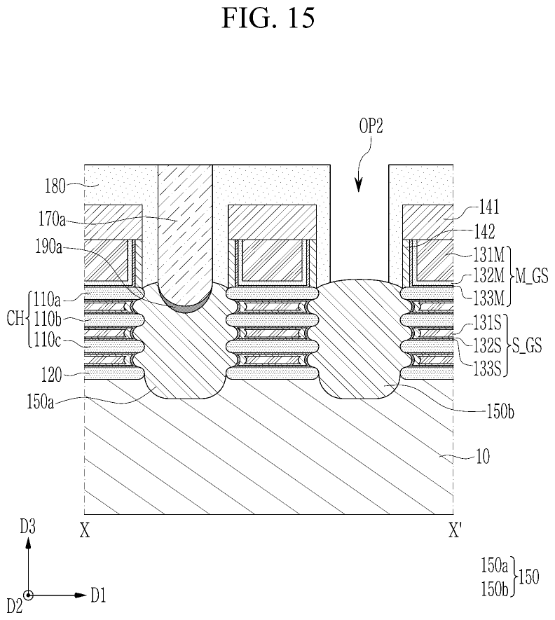

As shown in FIG. 15, a second opening OP2 may be formed by removing a portion of the interlayer insulation layer 180, where the portion of the interlayer insulation layer 180 may be removed by etching. A part of the interlayer insulation layer 180 may be etched using an etching solution having higher etch selectivity compared to the source/drain pattern 150, and/or a part of the interlayer insulation layer 180 may be etched by a dry etching process. Accordingly, a part of an upper surface of the second source/drain pattern 150b may be exposed. The second opening OP2 may be formed to form the recess pattern RC1 described with reference to FIG. 3

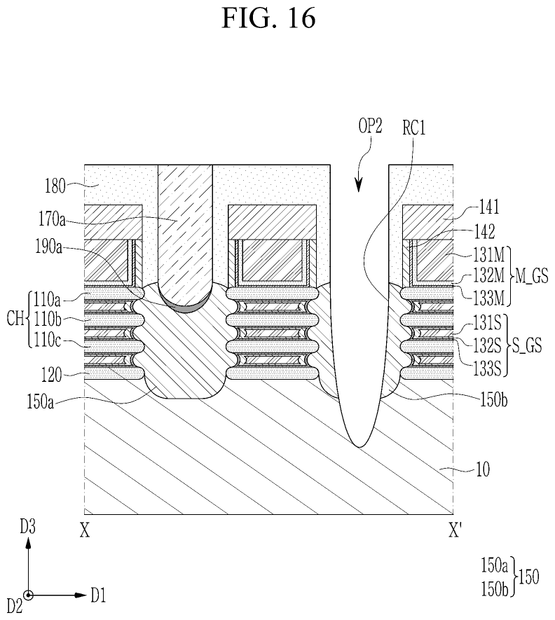

As shown in FIG. 16, the recess pattern RC1 may be formed by etching a part of the second source/drain pattern 150b and a part of the substrate 10. The second source/drain pattern 150b and the substrate 10 may be etched together through a single process; however, this is not restrictive, and the second source/drain pattern 150b and the substrate 10 may be sequentially etched through individual processes. The recess pattern RC1 may extend through the second source/drain pattern 150b in the third direction D3. One end of the recess pattern RC1 may extend into the substrate 10, where one end of the recess pattern RC1 may be adjacent to the bottom surface of the substrate 10 compared to a bottom surface of the second source/drain pattern 150b. The second source/drain pattern 150b and substrate 10 may be etched using an etching solution with higher etch selectivity compared to the interlayer insulation layer 180 for the source/drain pattern 150 or the substrate 10 and/or the second source/drain pattern 150b may be etched by a dry etching process. A part of the interlayer insulation layer 180 and the first through-hole via 170a may be masked, while the recess pattern RC1 is formed, so the interlayer insulation layer 180 and the first through-hole via 170a on the first source/drain pattern 150a may not be etched.

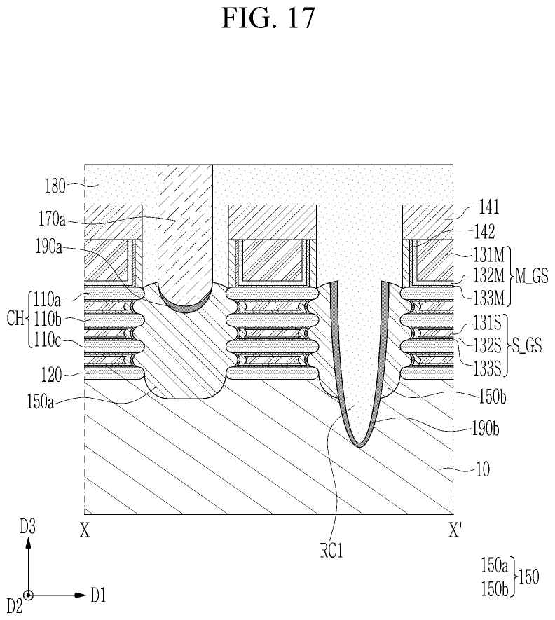

As shown in FIG. 17, a second silicide layer 190b may be formed inside the second opening OP2. The second silicide layer 190b may be formed along the profile of the sidewall and the bottom surface of recess pattern RC1. The second silicide layer 190b may be formed at an interface between the interlayer insulation layer 180 formed inside the recess pattern RC1 and the second source/drain pattern 150b. The second silicide layer 190b may also be formed at the interface between the interlayer insulation layer 180 and the substrate 10 formed inside the recess pattern RC1. The second silicide layer 190b may be formed along the second source/drain pattern 150b and the surface of the substrate 10 etched in the process of forming the recess pattern RC1. The second silicide layer 190b may be a metal silicide layer. In an embodiment, the second silicide layer 190b may be formed by a CVD method. The second silicide layer 190b may be selectively formed on the first source/drain pattern 150a and the surface of the substrate 10. The interlayer insulation layer 180 may be formed on the second silicide layer 190b, where the interlayer insulation layer 180 formed on the second silicide layer 190b may include the same insulating material as the interlayer insulation layer 180 that has already been formed on the source/drain pattern 150 and the gate structures M_GS and S_GS. The boundary between the interlayer insulation layer 180 formed later and the interlayer insulation layer 180 that has already been formed may not be recognized, where the interlayer insulation layer 180 forms a continuous layer.

In FIG. 17, the second silicide layer 190b is shown formed along the profile of the side wall and the bottom surface of the recess pattern RC1, but the second silicide layer 190b may be formed only on a part of the surface of the recess pattern RC1. For example, the second silicide layer 190b may be formed on the recess pattern RC1 and may not be formed on a part of the bottom surface The second silicide layer 190b may be formed at an interface of the interlayer insulation layer 180 and the second source/drain pattern 150b inside the recess pattern RC1, and may not be formed at an interface between the interlayer insulation layer 180 and the substrate 10 inside the recess pattern RC1. The second silicide layer 190b may be formed along the surface profile of the protruding recess pattern RC1.

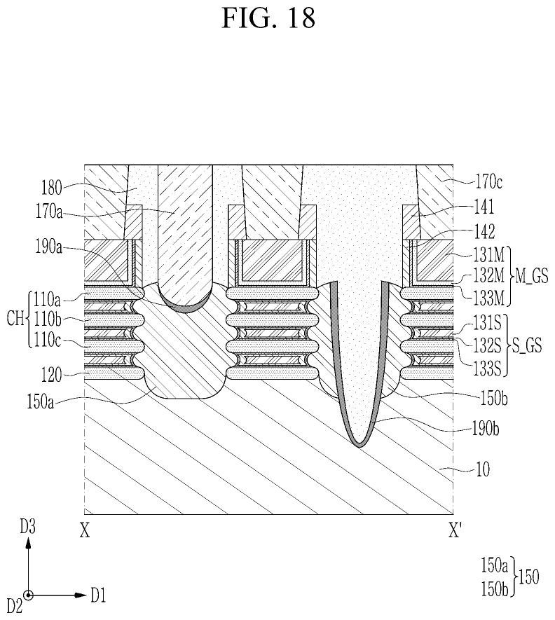

As shown in FIG. 18, a contact hole that extends through the capping layer 141 and exposes the main gate structure M_GS may be formed. Subsequently, a third through-hole via 170c that is electrically connected with the main gate structure M_GS may be formed by filling the contact hole. The third through-hole via 170c may penetrate the capping layer 141 and be electrically connected to the main gate structure M_GS.

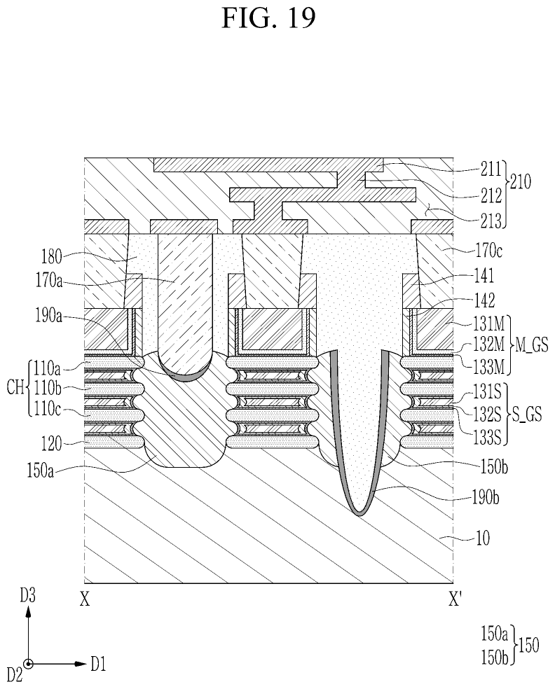

As shown in FIG. 19, an upper wiring structure 210 electrically connected with the first through-hole via 170a and the third through-hole via 170c may be formed on the interlayer insulation layer 180. The upper wiring structure 210 may include upper wires 211, upper vias 212, and an upper insulation layer 213. In an embodiment, the upper wiring structure 210 may include a plurality of layers of upper wires 211 formed through a repetitive process. After depositing a layer of the upper insulation layer 213 on an upper surface of the interlayer insulation layer 180, the layer of the upper insulation layer 213 may be patterned, and the upper wire 211 connected to the first through-hole via 170a or third through-hole via 170c may be formed. A layer of the upper insulation layer 213 may be deposited on the upper wire 211 and patterned, and an upper via 212 connected to an end of the first through-hole via 170a or third through-hole via 170c may be formed on the upper wire 211. An upper layer 211 electrically connected with the upper via 212 may be formed.

In various embodiments, the upper wires 211 and the upper vias 212 may include a metal (e.g., copper). The upper insulation layer 213 may be disposed on an upper surface of the interlayer insulation layer 180. The upper insulation layer 213 may cover the upper wires 211 and the upper vias 212, where the upper wires 211 and the upper vias 212 may be disposed in the upper insulation layer 213. The upper insulation layer 213 may include, for example, at least one of silicon oxide (Si0₂), silicon nitride (SiN), silicon oxynitride (SiON), or a low dielectric constant material.

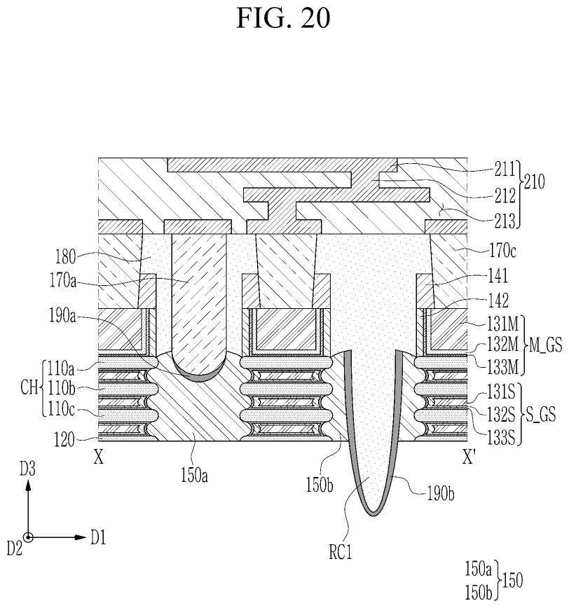

As shown in FIG. 20, the substrate 10 may be removed by performing an etching process, where the etching process may be, for example, a wet etching process and/or a dry etching process. The substrate 10 may be etched using an etching solution with higher etch selectivity compared to the second silicide layer 190b. A chemical mechanical polishing (CMP) process to thin the substrate 10 may be performed on the lower surface of substrate 10. With removal of the substrate 10, the source/drain patterns 150a and 150b, the second silicide layer 190b, and the dummy semiconductor layer 120 may be exposed. Referring to FIG. 20, a lower portion of the source/drain patterns 150a, and 150b and a part of a lower portion of the dummy semiconductor layer 120 may be etched. Accordingly, bottom surfaces of the source/drain patterns 150a and 150b and a bottom surface of the dummy semiconductor layer 120 may be at substantially at the same level (e.g., coplanar). In various embodiments, the dummy semiconductor layer 120 may be completely removed, such that the bottom surfaces of the source/drain patterns 150a and 150b may be substantially at the same level, as the bottom surface of the sub-gate structure S_GS.

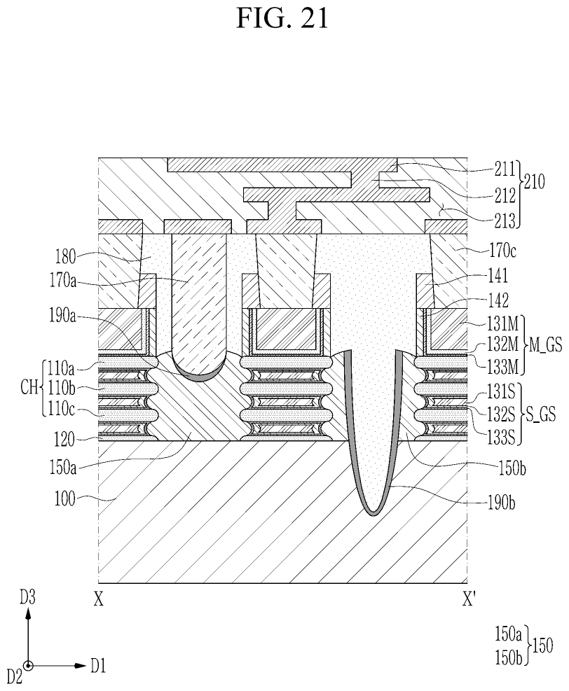

As shown in FIG. 21, a base insulation layer 100 that covers the source/drain patterns 150a and 150b, the second silicide layer 190b, and the dummy semiconductor layer 120 may be formed in an area where the substrate 10 is removed. Accordingly, the base insulation layer 100 may directly contact the source/drain patterns 150a and 150b, the second silicide layer 190b, and the dummy semiconductor layer 120. In an embodiment, the base insulation layer 100 may include an insulating material that is different from that of the interlayer insulation layer 180. For example, the base insulation layer 100 may include a silicon nitride (SiN).

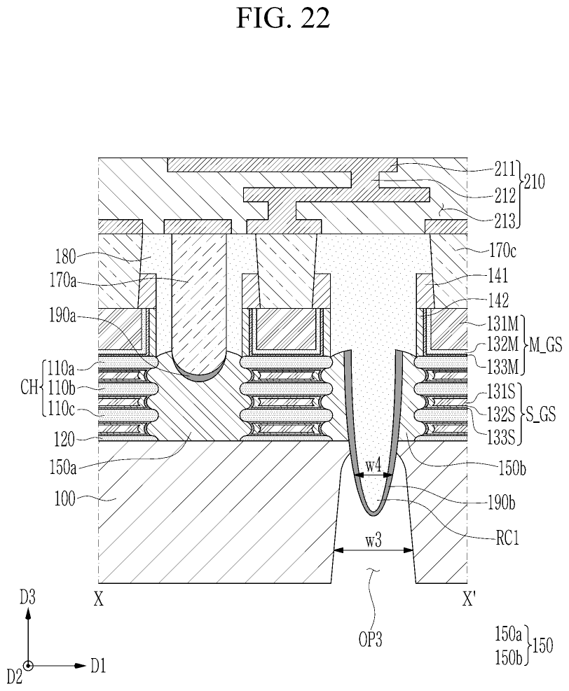

As shown in FIG. 22, photo and etching processes may be performed to etch a part of the base insulation layer 100, thereby forming a third opening OP3. A portion of the base insulation layer 100 may be etched using an etching solution with higher etch selectivity compared to the second silicide layer 190b. Accordingly, a portion of the recess pattern RC1 protruding through the second source/drain pattern 150b in the bottom surface direction of the base insulation layer 100 may be exposed. In an embodiment, a width of the third opening OP3 in the first direction D1 may be greater than a width w4 of the recess pattern RC1 in the first direction D1. In the process of exposing the recess pattern RC1 to form the second through-hole via 170b (refer to FIG. 2), a sufficient overlay margin can be secured.

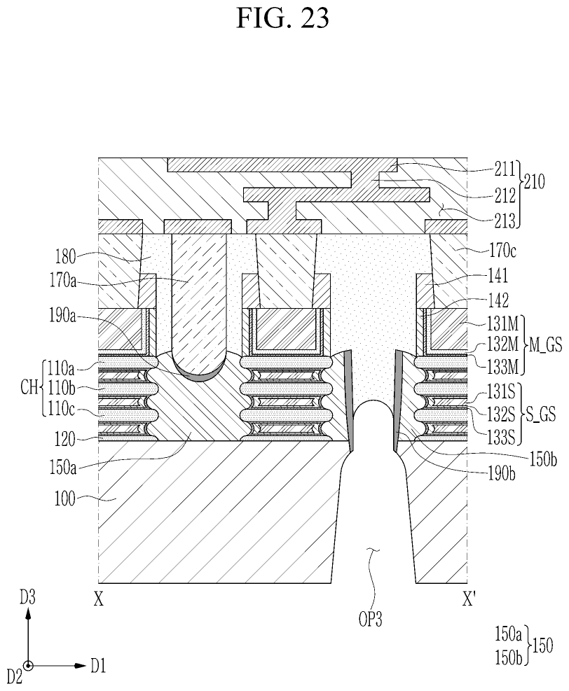

As shown in FIG. 23, a lower portion and parts of side walls of the recess pattern RC1 protruding towards the bottom surface direction of the base insulation layer 100 may be etched. A part of the second silicide layer 190b formed along the surface profile of the protruding recess pattern RC1 may be removed. The portion of the second silicide layer 190b may be removed using an etching solution having higher etch selectivity for the second silicide layer 190b compared to the base insulation layer 100. A part of the interlayer insulation layer 180 inside the protruding recess pattern RC1 may be removed. An etching solution with higher etch selectivity for the interlayer insulation layer 180 compared to the base insulation layer 100 and the second silicide layer 190b may be used. An area where the interlayer insulation layer 180 inside the recess pattern RC1 is etched may protrude farther in the direction of the upper surface of the second source/drain pattern 150b based on the interface between the second source/drain pattern 150b and the base insulation layer 100. An upper surface of the area where the interlayer insulation layer 180 inside the recess pattern RC1 is etched may be at a higher level than the interface between the second source/drain pattern 150b and the base insulation layer 100. The upper surface of the area where the interlayer insulation layer 180 inside recess pattern RC1 is etched may be at a lower level than the upper surface of the second source/drain pattern 150b.

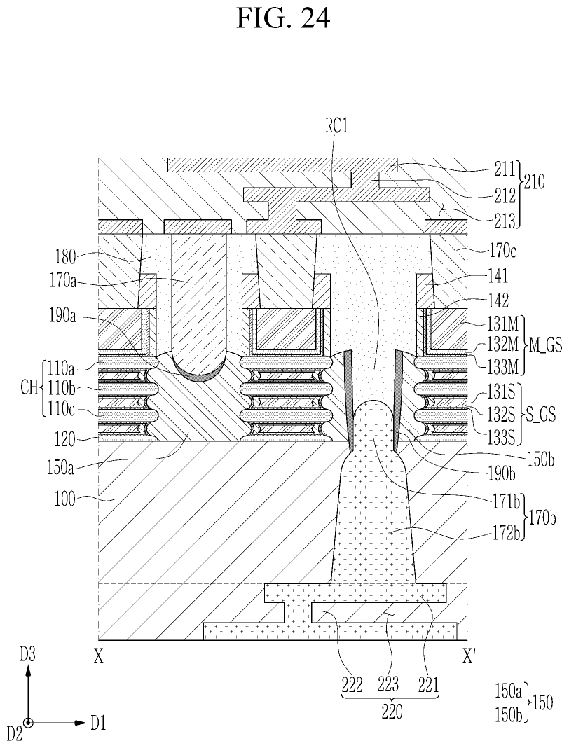

As shown in FIG. 24, the second through-hole 170b that is electrically connected with the second silicide layer 190b may be formed by filling the third opening OP3. The lower wiring structure 220 may be formed on the base insulation layer 100 and the second through-hole via 170b. The second through-hole via 170b may include at least one of a metal, a metal alloy, conductive metal nitride, conductive metal carbide, conductive metal oxide, conductive metal carbonitride, or a two-dimensional material. The metal may include at least one of titanium (Ti), tantalum (Ta), tungsten (W), nickel (Ni), cobalt (Co), or platinum (Pt). The conductive metal nitride may include at least one of titanium nitride (TiN), tantalum nitride (TaN), tungsten nitride (WN), nickel nitride (NiN), cobalt nitride (CON), or platinum nitride (PtN). The second through-hole via 170b may include a first area 171b that extends through the bottom surface of the recess pattern RC1 and protrudes into the recess pattern RC1, and a second area 172b that electrically connects the lower wiring structure 220 and the first area 171b.

In various embodiments, the lower wiring structure 220 may include lower wires 221, lower vias 222, and lower insulation layer 223. In an embodiment, the lower wiring structure 220 may include a plurality of layers of upper wires 211 formed through a repetitive process. A layer of the lower insulation layer 223 may be deposited on the bottom surface of base insulation layer 100 and then patterned, and the lower wire 221 connected to one end of the second area 172b of the second through-hole via 170b may be formed. A layer of the lower insulation layer 223 may be deposited and patterned, such that and the lower via 222 may be formed on the lower wire 221 connected to one end of the second area 172b. The lower wire 221 connected with the other end of the lower via 222 may be formed.

In various embodiments, the lower wires 221 and the lower vias 222 may include a metal (e.g., copper). The lower insulation layer 223 may be disposed on the bottom surface of the base insulation layer 100. The lower insulation layer 223 may cover the lower wires 221 and the lower vias 222. The lower wires 221 and the lower vias 222 may be disposed inside the lower insulation layer 223. The lower insulation layer 223 may include, for example, at least one of silicon oxide (SiO₂), silicon nitride (SiN), silicon oxynitride (SiON), or low dielectric constant layers.

IN FIG. 20 to FIG. 24, the process of forming the base insulation layer 100, the second through-hole via 170b, and the lower wiring structure 220 may be performed by rotating the semiconductor device according to the embodiment. Specifically, after rotating the semiconductor device, the semiconductor device may be attached on a separate carrier substrate (not shown). Accordingly, the upper surface of the upper wiring structure 210 may be in contact with an upper surface of the carrier substrate, and the bottom surface of the substrate 10 may be exposed. An adhesive member may be disposed between the upper surface of the upper wiring structure 210 and the carrier substrate. The carrier substrate and the adhesive member may be removed from the semiconductor device after forming the lower wiring structure 220.

While various embodiments have been described in this disclosure, it is to be understood that the inventive concept and claims are not limited to the disclosed embodiments, and various modifications and equivalent arrangements are included within the spirit and scope of the appended claims.

What is claimed is:

1. A semiconductor device comprising:
a base insulation layer having a first surface and a second surface facing each other with a thickness therebetween;
a channel layer on the first surface of the base insulation layer;
a first source/drain pattern and a second source/drain pattern on the first surface of the base insulation layer and arranged in a first direction with the channel layer therebetween;
a gate structure, that extends in a second direction crossing the first direction on the first surface of the base insulation layer, and surrounds the channel layer;
a first silicide layer on a side wall of a recess pattern that penetrates the first source/drain pattern in a third direction that is perpendicular to the first direction and the second direction; and
an interlayer insulation layer that is inside of the recess pattern.

2. The semiconductor device of claim 1, wherein:
the interlayer insulation layer covers the channel layer, the first source/drain pattern, the second source/drain pattern, and the gate structure.

3. The semiconductor device of claim 1, wherein:
the base insulation layer comprises an insulating material that is different from that of the interlayer insulation layer.

4. The semiconductor device of claim 1, wherein:
the first silicide layer directly contacts the first source/drain pattern.

5. The semiconductor device of claim 1, further comprising:
a lower wiring structure on the second surface of the base insulation layer; and
a first through-hole via extending through base insulation layer in the third direction, wherein a first end is electrically connected with the lower wiring structure and a second end is electrically connected with the second silicide layer.

6. The semiconductor device of claim 5, wherein:
the first through-hole via comprises a first area that penetrates a bottom surface of the recess pattern and protrudes into the recess pattern, and a second area electrically connecting the lower wiring structure and the first area.

7. The semiconductor device of claim 6, wherein:
a maximum width of the first area in the first direction is smaller than a maximum width of the second area in the first direction.

8. The semiconductor device of claim 1, further comprising:
a second silicide layer on an upper surface of the second source/drain pattern;
an upper wiring structure on a first surface of the interlayer insulation layer; and
a second through-hole via extending through the interlayer insulation layer in the third direction, wherein a first end of the first through-hole via is electrically connected to the upper wiring structure, and a second end is electrically connected to the second silicide layer.

9. The semiconductor device of claim 1, wherein:
the channel layer overlaps the silicide layer in the first direction.

10. A method of manufacturing a semiconductor device, comprising:
forming a channel layer, a first source/drain pattern, and a second source/drain pattern arranged in a first direction on a first surface of a substrate;
forming a gate structure, that extends in a second direction crossing the first direction on the first surface of the substrate, and surrounds the channel layer;
forming an interlayer insulation layer on the channel layer, the first source/drain pattern, the second source/drain pattern, and the gate structure;
forming a recess pattern that penetrates the first source/drain pattern in a third direction that is perpendicular to the first direction and the second direction; and
forming a first silicide layer extending along a surface profile of the recess pattern; and
filling the inside of the recess pattern with an insulating material.

11. The method of manufacturing the semiconductor device of claim 10, wherein the interlayer insulation layer includes a same insulating material as the insulating material filled inside of the recess pattern.

12. The method of manufacturing the semiconductor device of claim 11, further comprising:
forming a second through-hole via penetrating the interlayer insulation layer in the third direction, wherein one end of the second through-hole via is electrically connected with a second silicide layer on the second source/drain pattern; and
forming an upper wiring structure that is electrically connected with the other end of the second through-hole via on the interlayer insulation layer.

13. The method of manufacturing the semiconductor device of claim 10, further comprising:
removing at least a portion of the substrate that overlaps the channel layer, the first and second source/drain patterns, and the gate structure in the third direction; and
forming a base insulation layer in an area where the substrate is removed,
wherein the base insulation layer comprises an insulating material that is different from the insulating material of the interlayer insulation layer.

14. The method of manufacturing the semiconductor device of claim 13, wherein:
the base insulation layer comprises a first surface that is adjacent to the channel layer, the first and second source/drain patterns, and the gate structure, and a second surface facing the first surface with a thickness therebetween, and
the method of manufacturing the semiconductor device further comprises:
forming a first through-hole via penetrating the base insulation layer in the third direction, wherein one end is connected with the first silicide layer; and
forming a lower wiring structure that is electrically connected with the other end of the first through-hole via on the second surface of the base insulation layer.

15. The method of manufacturing the semiconductor device of claim 14, wherein:
the forming of the first through-hole via further comprises:
exposing a part of the recess pattern by removing a part of the base insulation layer overlapping the recess pattern in the third direction;
removing the part of the recess pattern; and
filling an area where the part of the base insulation layer is removed and an area where the part of the recess pattern is removed with a metal material.

16. The method of manufacturing the semiconductor device of claim 15, wherein:
the removing of the part of the recess pattern further comprises:
removing the first silicide layer on the recess pattern surface and removing a part of an insulating material in the recess pattern, and
a height of an area where the part of the insulating material is removed is higher than a height of the first surface of the the base insulation layer.

17. The method of manufacturing the semiconductor device of claim 14, wherein:
the first through-hole via comprises a first area that penetrates a bottom surface of the recess pattern and protrudes into the recess pattern, and a second area connecting the lower wiring structure and the first area, and
a maximum width of the first area in the first direction is smaller than a maximum width of the second area in the first direction.

18. A semiconductor device comprising:
a base insulation layer that includes a first surface and a second surface facing each other with a thickness therebetween;
a channel layer on the first surface of the base insulation layer;
a first source/drain pattern and a second source/drain pattern on the first surface of the base insulation layer, and arranged in a first direction, wherein the channel layer is therebetween;
a gate structure that extends in a second direction crossing the first direction on the first surface of the base insulation layer, and surrounds the channel layer in the second direction;
a first silicide layer that is on the first source/drain pattern;
an interlayer insulation layer that covers the channel layer, the source/drain patterns, and the gate structure;
an upper wiring structure on the interlayer insulation layer;
a lower wiring structure on the second surface of the base insulation layer;
a first through-hole via that penetrates the base insulation layer in the third direction, and connects the recess pattern and the lower wiring structure; and
a second through-hole via that penetrates the interlayer insulation layer in the third direction, and electrically connects the second source/drain pattern with the upper wiring structure.

19. The semiconductor device of claim 18, wherein:
the first through-hole via comprises a first area that penetrates a bottom surface of the recess pattern and protrudes into the recess pattern, and a second area connecting the lower wiring structure and the first area.

20. The semiconductor device of claim 19, wherein:
a maximum width of the first area in the first direction is smaller than a maximum width of the second area in the first direction.
